(19) United States
(12) Patent Application Publication
(10) Pub. No.: US 2024/0186361 A1
(43) Pub. Date: Jun. 6, 2024

(54) VISIBLE AND INFRARED IMAGE SENSOR

(71) Applicant: Commissariat à I'Énergie Atomique et aux Énergies Alternatives, Paris (FR)

(72) Inventor: Sébastien Becker, Grenoble Cedex 9 (FR)

(73) Assignee: Commissariat à I'Énergie Atomique et aux Énergies Alternatives, Paris (FR)

(21) Appl. No.: 18/520,191

(22) Filed: Nov. 27, 2023

(30) Foreign Application Priority Data
Dec. 1, 2022 (FR) 2212606

(51) Int. Cl. H01L 27/146

(52) U.S. Cl. CPC H01L 27/14669; H01L 27/1463; H01L 27/14636; H01L 27/14667

(57) ABSTRACT

A visible and infrared image sensor, including: a first active layer for detecting visible radiation, in which a plurality of visible detection pixels are defined; and superimposed on the first active layer, a second active layer for detecting infrared radiation, in which a plurality of infrared detection pixels are defined, the sensor further including, on the side of the face of the second active layer opposite the first active layer, a control integrated circuit superimposed on the first and second active layers, wherein the sensor includes isolation trenches extending vertically through at least part of the thickness of the second active layer, and laterally delimiting in the second active layer islands or mesas forming the infrared detection pixels.

### CROSS REFERENCE TO RELATED APPLICATIONS

This application claims priority to French application number 2212606, filed Dec. 1, 2022, the contents of which is incorporated by reference in its entirety.

### TECHNICAL FIELD

The present application relates to the field of image acquisition devices, and more particularly to image acquisition devices adapted to acquire, simultaneously or successively, a visible image and an infrared image of a scene, for example for applications requiring the acquisition, simultaneously or successively, of a visible two-dimensional (2D) image of a scene and a depth map of the same scene.

### BACKGROUND ART

Patent applications US2019191067 and US2021305206, previously filed by the applicant, describe examples of devices comprising a visible image sensor and an infrared image sensor superimposed on each other. French patent application FR2105161 filed on May 18, 2021 and entitled “Method for manufacturing an optoelectronic device” describes, in relation to its FIGS. 10A to 10D, an example of a method for manufacturing a device comprising a visible detector and an infrared detector superimposed on each other. French patent application FR2113457 filed on Dec. 14, 2021 and entitled “Sensor for sensing visible and infrared images and method for producing such a sensor” describes another example of a device comprising a visible detector and an infrared detector superimposed and a method for manufacturing such a device.

It would be desirable to improve at least in part some aspects of known visible and infrared image sensors, as well as known methods for manufacturing such sensors.

### SUMMARY OF INVENTION

One embodiment provides a visible and infrared image sensor, comprising:
a first active layer for detecting visible radiation, in which a plurality of visible detection pixels are defined; and
superimposed on the first active layer, a second active layer for detecting infrared radiation, in which a plurality of infrared detection pixels are defined,

the sensor further comprising, on the side of the face of the second active layer opposite the first active layer, a control integrated circuit superimposed on the first and second active layers,

wherein the sensor comprises isolation trenches extending vertically through at least part of the thickness of the second active layer, and laterally delimiting in the second active layer islands or mesas forming the infrared detection pixels.

According to one embodiment, the insulation trenches pass completely through the second active layer.

According to one embodiment, the insulation trenches extend over only part of the thickness of the second active layer.

According to one embodiment, the second active layer defines, in each infrared detection pixel, a vertical resonant optical cavity for said infrared radiation.

According to one embodiment, the first active layer and the second active layer are separated by a non-metallic interface layer, the interface layer being in contact, via a first face, with the first active layer and, via a second face, with the second active layer.

According to one embodiment, the interface layer is made of silicon oxide.

According to one embodiment, the interface layer comprises electrical routing elements made of doped polycrystalline silicon.

According to one embodiment, the first active layer is made of silicon.

According to one embodiment, the second active layer is made of an inorganic semiconductor material.

According to one embodiment, the second active layer contains germanium or silicon, for example a silicon-germanium alloy or a silicon-germanium-carbon alloy.

According to one embodiment, the second active layer contains InGaAs or any other sensing semiconductor material from the III-V semiconductor family.

According to one embodiment, the sensor comprises a reflective layer, for example made of metal or a doped semiconductor material, on the side of the face of the second active layer opposite the first active layer.

According to one embodiment, the sensor also comprises a doped semiconductor layer arranged between the first active layer and the second active layer, and electrically connecting the infrared detection pixels of the sensor via their face facing the first active layer.

According to one embodiment, the sensor comprises conductive vias extending vertically through the isolation trenches, and electrically connecting active elements of the visible sensing pixels to the control integrated circuit.

A further embodiment provides a method for manufacturing a visible and infrared image sensor, comprising the following successive steps:
a) providing a first active layer for detecting visible radiation, in which a plurality of visible detection pixels are defined;
b) attaching a second active layer for detecting infrared radiation to the first active layer by direct bonding;
c) forming isolation trenches extending laterally through the second active layer and laterally delimiting in the second active layer islands or mesas defining a plurality of infrared detection pixels in the second active layer; and
d) arranging, on the side of the face of the second active layer opposite the first active layer, a control integrated circuit superimposed on the first and second active layers.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, FIG. 1D, FIG. 1E, and FIG. 1F are cross-sectional views illustrating steps of an example method for manufacturing a visible and infrared image sensor according to one embodiment;

FIG. 2 is a cross-sectional view illustrating a variant of a visible and infrared image sensor according to one embodiment; and

FIG. 3 is a cross-sectional view illustrating another variant of a visible and infrared image sensor according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, manufacturing photodiodes and control circuits for the visible and infrared detection pixels have not been detailed, as the manufacturing of these elements is within the abilities of those skilled in the art on the basis of the indications in the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

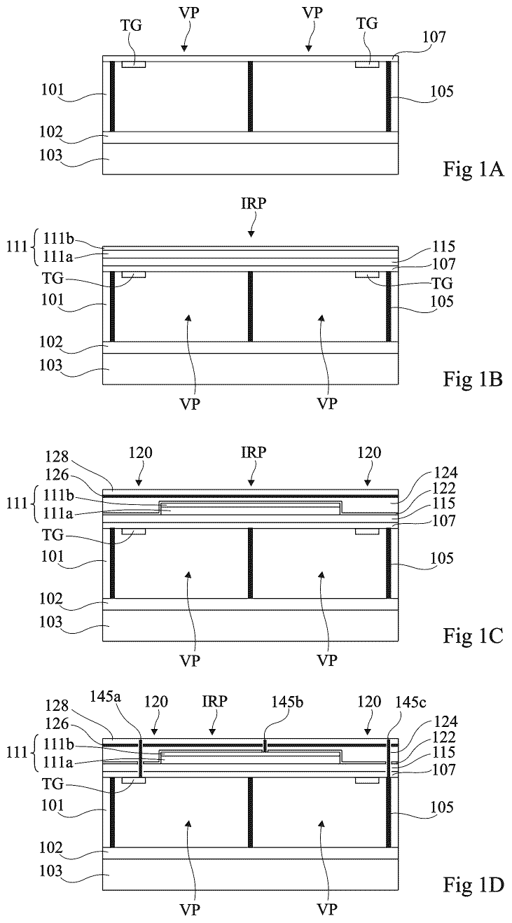

FIGS. 1A to 1F are cross-sectional views illustrating steps of an example method for manufacturing a visible and infrared image sensor according to one embodiment.

FIG. 1A illustrates very schematically a first structure comprising an active visible detection layer 101, in which are defined a plurality of pixels VP for detecting visible radiation, for example arranged in a matrix pattern. The layer 101 is made of a semiconductor material, such as crystalline silicon. Layer 101 is, for example, the top semiconductor layer of an SOI (Silicon On Insulator) stack. In this example, the SOI stack comprises an electrically insulating layer 102, e.g. made of silicon oxide, with its top side in contact with the lower face of layer 101, and a support layer 103, e.g. made of silicon, with its upper face in contact with the lower face of the insulating layer 102. The thickness of the active layer 101 is, for example, between 2 and 10 μm, for example of the order of 4 μm.

Each pixel VP comprises an active part formed in and on the 101 active layer. The active part comprises, for example, a photodiode (not detailed in the figure) and a reading node (not visible in the cross-sectional view of FIG. 1A) formed on the upper face side of layer 101. For example, the active part of each pixel VP also includes a vertical or planar transfer gate TG, allowing enabling the transfer of photo-generated electrical charges from the photodiode to the sense node. By way of example, the dimensions, in plan view, of the transfer gate TG of each visible pixel VP are of the order of 100 to 300 nm. The top-view dimensions of the sense node of each visible pixel VP are, for example, also in the order of 100 to 300 nm. By way of example, the transfer gate TG and the sense node of each visible pixel VP each have a generally square shape of the order of 150 nm on a side. However, the embodiments described are not limited to these examples of shapes and dimensions. The active part of each pixel VP may optionally comprise one or more additional transistors, not detailed. The various elements forming the active part of each pixel VP will not be detailed further, as the embodiments described are compatible with all or most known photo-sensing pixel structures, for example with one or more transistors.

In this example, the active parts of the pixels VP are separated laterally from each other by isolation trenches or walls 105 extending vertically through the active layer 101, for example over the entire thickness of the layer 101. The trenches 105 are capacitive isolation trenches, for example of the CDTI type (Capacitive Deep Trench Isolation), each comprising a core or central wall made of an electrically conductive material, for example doped polycrystalline silicon, and a lateral coating made of an electrically insulating material, for example silicon oxide. However, the embodiments described are not limited to this particular case. By way of example, trenches 105 are insulating trenches entirely filled with a dielectric material, such as silicon oxide, e.g. DTI trenches (Deep Trench Isolation). Alternatively, trenches 105 are filled with an insulating coating, e.g. oxide, e.g. 12-13 nm thick, followed by a conductive layer, e.g. doped polycrystalline silicon, e.g. 50 nm thick, followed by a dielectric filler material, e.g. an oxide, e.g. 80 nm thick. For example, the insulating trenches 105 are formed from the upper surface of the active layer 101. The active parts of the pixels VP are, for example, all identical, apart from manufacturing dispersions.

In the example shown, the active layer 101 is coated with a passivation layer 107 of an electrically insulating material, such as silicon oxide. The layer 107 extends, for example, continuously over the entire surface of the structure. For example, the lower surface of the layer 107 is in contact with the upper surface of the active layer 101.

FIG. 1B illustrates the structure obtained at the end of a step of transferring and attaching an active infrared detection layer 111 to the upper face of the structure shown in FIG. 1A.

By way of example, the active infrared detection layer 111 is initially arranged on one face of a support substrate (not shown), for example made of silicon. Layer 111 is epitaxially formed on said face of the support substrate. In this example, a passivation layer 115 is then formed on the face of the active layer 111 opposite the support substrate, for example in contact with the face of the active layer 111 opposite the support substrate. Layer 115 is made of an electrically insulating material, such as the same material as layer 107, e.g. silicon oxide. Layer 115 extends, for example, continuously over the entire surface of active layer 111.

The structure comprising the support substrate, the active layer 111, and the passivation layer 115 is then transferred and attached to the structure shown in FIG. 1A, after which the support substrate is removed to expose the face of active layer 111 opposite the passivation layer 115, i.e. its upper face in the orientation shown in FIG. 1B. By way of example, the active layer 111 is attached by direct bonding (also known as molecular bonding) full plate of the lower face of the dielectric layer 115 to the upper side of the layer 107. At this stage, the active layer 111 extends continuously and with a substantially uniform thickness over the entire upper surface of the underlying visible sensing structure.

The active layer 111 comprises a semiconductor material absorbing infrared radiation intended to be detected by the sensor, for example radiation emitted by an infrared source of an acquisition system comprising the visible and infrared image sensor, for example radiation with a wavelength between 900 nm and 2 μm, for example radiation with a wavelength of the order of 940 nm or radiation with a wavelength of the order of 1.4 μm.

The active layer 111 is, for example, a stack of semiconductor multilayers. The active layer 111 is made, for example, of germanium or a germanium-based semiconductor alloy, such as silicon-germanium.

More generally, layer 111 can be made of any other semiconductor material suitable for converting infrared radiation in the wavelength range of interest into electrical charges, for example:
Group IV semiconductors, such as silicon (Si), germanium (Ge), or a germanium-tin alloy (GeSn), or an alloy comprising one or more of these materials;
III-V semiconductors, such as an indium-gallium-arsenic (InGaAs) alloy with an indium phosphide (InP) layer, or an indium-gallium-arsenic phosphide (InGaAsP) alloy;
materials based on quantum dots, e.g. colloidal quantum dots based on indium arsenide (InAs), lead sulfide (PbS), lead selenide (PbSe), indium antimonide (InSb), or indium arsenide antimonide (InAsSb); or
organic semiconductor materials or perovskites.

Preferably, the active layer 111 is inorganic.

In the example shown, the active layer 111 comprises a lower layer 111a doped with a first type of conductivity, for example N-type, and an upper layer 111b doped with a second type of conductivity, for example P-type. The layers 111a and 111b are doped, for example, by diffusion or implantation of doping elements before or after the step of transferring the active layer 111 to the upper surface of the visible detection structure. Alternatively, layers 111a and 111b are in-situ doped as they are formed on the support substrate, before the step of transferring active layer 111 to the upper face of the visible detection structure. In this example, the interface between layers 111a and 111b defines a PN junction of the future infrared detection pixels IRP of the device.

By way of example, at this stage, the layers 111a and 111b each extend continuously and with substantially uniform thickness over the entire surface of the underlying visible sensing structure (full plate).

Alternatively, the active layer 111 can comprise localized doped zones aligned laterally with respect to elements of the underlying visible detection structure and defining the future infrared detection pixels IRP of the device. In this case, the localized doped zones can be formed before or after the transfer of the active layer 111 to the upper face of the visible detection structure.

The infrared detection pixels IRP of the device are arranged in a matrix pattern, for example. The infrared detectors of the pixels IRP can be of different types, depending on the type of infrared detection required. By way of example, the infrared detectors are conventional PN junction photodiodes for measuring infrared flux. Alternatively, the infrared detectors are PIN-type photodiodes. Alternatively, the infrared detectors are single-photon avalanche detection (SPAD) photodiodes. Alternatively, the infrared detectors are current-assisted photonic demodulators (CAPDs), for example of the type described in the article “Design and Characterization of Current-Assisted Photonic Demodulators in 0.18-μm CMOS Technology” by Gian-Franco Dalla Betta et al, to measure a modulation of an infrared signal to provide depth information, or any other type of photodetector. The various elements forming infrared detection pixels IRP will not be detailed further, as the embodiments described are compatible with all or most known infrared detection pixel structures.

FIG. 1C illustrates the structure obtained after a step of etching, from the upper face of the active layer 111, trenches 120 extending vertically through at least part of the thickness of the active layer 111 and laterally delimiting the infrared detection pixels IRP of the device. In this example, each pixel IRP is completely surrounded and separated from the other pixels by trenches 120. In this way, the trenches 120 laterally delimit islands or mesa structures in the active layer 111, each island or mesa structure containing an infrared detector and corresponding to an infrared detection pixel IRP of the device. By way of example, when viewed from above, the trenches 120 form a grid laterally separating the pixels IRP of the device from one another.

The infrared detection pixels IRP, for example, are aligned with the underlying VP visible detection pixels. The pitch (centre-to-centre distance between two neighbouring pixels) of the pixel IRP matrix can be different from the pitch of the pixel VP matrix. For example, the pitch of the pixel IRP matrix is twice as large (in both row and column directions) as the pitch of the pixel VP matrix.

In the example shown, the trenches 120 extend vertically through the entire thickness of the active layer 120, and open onto the upper surface of the passivation layer 115.

FIG. 1C further illustrates a step of depositing, after the trenches 120 have been formed, a passivation layer 122 on the upper surface of the structure. The layer 122 is made, for example, of a dielectric material such as silicon oxide or silicon nitride. The layer 122 is deposited, for example, by a conformal deposition process. By way of example, the thickness of the passivation layer 122 is between a few tens and a few hundreds of nanometres, for example between 20 and 500 nanometres, for example of the order of 50 nanometres.

The layer 122 extends on and in contact with the top and sides of the active layer 111. In particular, the layer 122 enables the sides of the active layer 111 to be passivated after the step of etching the trenches 120. In the example shown, the layer also extends on and in contact with the upper face of the layer 115 at the bottom of the trenches. By way of example, the layer 122 extends continuously and with a substantially uniform thickness on the entire upper surface of the structure obtained after forming the trenches 120.

FIG. 1C further illustrates a step of planarizing the upper surface of the structure. To this end, after forming the passivation layer 122, a dielectric material 124 for filling the trenches 120, such as silicon oxide, is deposited on the upper face of the structure, to a thickness greater than the depth of the trenches 120, so as to completely fill the trenches 120. A step of planarizing the upper surface of the structure is then performed, for example by chemical-mechanical polishing. In the example shown, at the end of the step of planarizing, a part of the thickness of the dielectric filling material 124 covers the islands or mesas of the active layer 111 of the pixels IRP of the device. By way of example, the thickness of dielectric filler material 124 covering the islands or mesas of the active layer 111 is between a few tens and a few hundreds of nanometres, for example between 20 and 500 nanometres, for example of the order of 50 nanometres. As a non-limiting example, prior to depositing the dielectric filler material, a planarization supper layer, for example of silicon nitride, is deposited on the upper face of the structure. The passivation layer 122 may, for example, act as a supper layer. Planarizing is interrupted on the supper layer, and then a thin layer of filler material 124 can be redeposited on the upper face of the structure.

FIG. 1C further illustrates an optional step for forming a layer 126 reflecting in the detection wavelength range of the infrared pixels IRP on the upper face of the structure, for example in contact with the upper face of the dielectric layer 124. Layer 126, also known as an optical reflector, covers in particular the islands or mesa structures of the active layer 111, and increases absorption in the infrared detectors of the corresponding pixels IRP, and in the detectors of visible pixels VP in the case of a broad-spectrum reflective layer 126, for example a metallic layer. By way of example, the optical reflector 126 extends continuously over the entire upper surface of the structure. According to a not illustrated alternative, the reflective layer 126 can be deposited directly on the passivation layer 122, before depositing the filler material 124. The reflective layer 126 can then be used as a supper layer during the step of planarizing the upper surface of the structure after depositing the filler material 124.

The optical reflector 126 is, for example, a layer of a reflective metal, e.g. titanium, aluminum, copper, or an alloy based on one or more of these materials. Alternatively, optical reflector 126 is a layer of highly doped silicon or germanium, e.g. N-type or P-type, e.g. with a doping level of the order of 10²⁰ atoms/cm³ or greater, e.g. with a thickness of the order of 400 nm or greater.

Alternatively, reflective layer 126 can be a Bragg mirror consisting of alternating semiconductor layers or dielectric layers with different refractive indices, for example alternating silicon (Si) layers and silicon oxide (SiO₂) or silicon nitride (SiN) layers, or alternating layers of silicon oxide (SiO₂) and layers of silicon nitride (SiN), or alternating layers of silicon oxide (SiO₂) and layers of hafnium oxide (HfO₂), or any other pair of materials suitable for reflecting the targeted infrared wavelength. Alternatively, the structure can be adapted to reflect both visible and infrared wavelengths.

In the case where the active infrared detection layer 111 is made of a III-V semiconductor material, the reflective layer 126 can be a Bragg mirror consisting of alternating epitaxial layers of III-V materials, such as alternating layers of aluminium arsenide (AlAs) and gallium arsenide (GaAs). In this case, the stack can be epitaxied following layer 111, before depositing the passivation layer 122.

In the example shown, a top passivation dielectric layer 128, for example of silicon oxide, is additionally formed on and in contact with the upper face of the optical reflector 126. Layer 128 extends, for example, continuously and with uniform thickness over the entire upper surface of the structure.

FIG. 1D illustrates the structure obtained at the end of the subsequent steps of forming conductive contact vias, starting from the upper face of the structure shown in FIG. 1C. In this step, electrical contact is made with the contact regions of the visible VP and infrared IRP pixels, and possibly with the conductive regions of the insulating trenches 105 (if these trenches are polarized capacitive insulating trenches).

FIG. 1D shows an insulated conductive via 145a extending vertically through layers 128, 126, 124, 122, 115, and 107, and individually contacting the charge transfer gate TG of a visible sensor pixel VP. Although not shown in the figure, a via 145a for contacting the transfer gate TG can be provided for each visible pixel VP of the sensor. The sense node of each visible pixel VP of the sensor can also be connected by a vertical via (not shown in the figure). Other vias, not detailed in the figures, can be provided to contact other active elements of the visible pixel.

Furthermore, in this example, for each infrared detection pixel IRP, an insulated conductive via 145b extending vertically through layers 128, 126, and 124 individually contacts a contact region of an active zone of the photosensitive detector of the pixel IRP. In the example shown, the via 145b contacts the upper layer 111b of the island or mesa active of the layer 111 of the photosensitive detector of the pixel IRP. A second insulated conductive via (not shown) can be provided for each pixel IRP, contacting another contact region of the active zone of the photosensitive detector of the pixel IRP. By way of example, this second via (not shown) is in contact with the lower layer 111a of the island or mesa 111 of the active layer of the photosensitive detector of the pixel IRP. In practice, as with the pixel VP, one or more other vias, not detailed in the figures, may be provided to contact one or more other contact zones of the pixel IRP.

FIG. 1D further shows an insulated via conductor 145c extending vertically through layers 128, 126, 124, 122, 115, and 107, and contacting a conductive region of an insulating trench 105 of a visible sensor pixel VP.

Preferably, the conductive vias intended to make contact with elements of the visible pixels VP are arranged opposite the insulating trenches 120 that laterally delimit the detection pixels IPR of the sensor. In this way, these vias do not pass through the active layer 111, or pass only through a reduced thickness of the active layer 111 (in the case where the trenches 120 extend over only part of the thickness of the active layer 111). In particular, this allows the dark currents associated with interface defects with the active layer 111 to be limited.

FIG. 1E illustrates the structure obtained at the end of subsequent steps of forming an interconnect stack 150 on and in contact with the upper face of the structure shown in FIG. 1D. The interconnection stack 150 comprises alternating insulating and conducting levels defining interconnection and routing tracks and vias for the various sensor components. In particular, the interconnection stack comprises metallizations through their lower faces are in contact with the upper faces of the contact vias formed in the previous step. The formation of the interconnection stack 150 can include successive stages of depositing and etching insulating and conducting layers, for example metallic, on the upper face of the structure shown in FIG. 1D.

In the example shown, the interconnect stack 150 has a hybrid planar upper surface (also known as the connection face) comprising alternating conductive and insulating regions.

FIG. 1F illustrates the structure obtained at the end a step of transferring and attaching an electronic control circuit 160, for example a CMOS circuit, onto and in contact with the upper face of the structure shown in FIG. 1E. In FIG. 1F, the structure is turned upside down with respect to the orientation of FIG. 1E. Thus, in FIG. 1F, the control circuit 160 is arranged on the lower face side of the interconnection stack 150. The electronic control circuit 160 includes, for example, circuits for reading visible pixels VP and infrared pixels IRP.

In the example shown, the electronic circuit 160 is formed from an SOI structure comprising a substrate 161 coated with an insulating layer 162, itself coated with a semiconductor layer 163 in and on which components 165, for example MOS transistors, are formed. The electronic circuit 160 further comprises, on the side of the semiconductor layer opposite the substrate 161, an interconnection stack 167 having a connection face (upper face in the orientation of FIG. 1F) symmetrical with respect to the connection face (lower face in the orientation of FIG. 1F) of the interconnection stack 150. The electronic circuit 160 is attached and electrically connected to the structure of FIG. 1E, for example by direct bonding of the upper face (in the orientation of FIG. 1F) of the interconnection stack 167 to the lower face of the stack 150. The bonding may be a hybrid direct bond of the copper/oxide type.

Alternatively, rather than using an SOI structure, the electronic control circuit 160 is made from a less expensive bulk semiconductor substrate.

FIG. 1F further illustrates, after transferring and attaching the electronic control circuit 160, a step for removing the support substrate 103 from the SOI structure used to form the visible detection structure (FIG. 1A), and then for forming optical elements, for example filtering elements and/or focusing elements, on the side of the light-exposure face of the sensor, i.e. its upper face in the orientation of FIG. 1F.

In this example, a colour filter 181 is formed above each visible pixel VP, adapted to let through only part of the visible spectrum. By way of example, separate visible pixels VP may be surmounted by separate colour filters 181. By way of example, first visible pixels VP are surmounted by a filter 181 adapted to let through predominantly green light, second visible pixels VP are surmounted by a filter 181 adapted to let through predominantly red light, and third visible pixels VP are surmounted by a filter 181 adapted to let through predominantly blue light. The colour filters are designed to let through infrared light intended to be detected by the infrared pixels IRP. For example, the colour filters are made of coloured resin.

In this example, a microlens is further formed above each visible pixel VP, adapted to focus incident light into a photosensitive zone of the underlying pixel VP.

Alternatively, the initial SOI structure 103-102-101 can be replaced by a solid semiconductor substrate, e.g. made of silicon. In this case, a step of thinning the substrate from its upper face (in the orientation shown in FIG. 1F) should be performed before depositing the optical elements.

An advantage of the embodiment described in relation to FIGS. 1A to 1F is that the island or mesa structure of the active infrared detection layer allows the optical cross-talk and electrical crosstalk between adjacent infrared detection pixels IPR to be limited.

Note that in the example shown, the isolation trenches 120 extend through the entire thickness of the active infrared detection layer 111, delimiting disjoint islands of layer 111 defining the pixels IPR of the sensor. As previously indicated, the trenches 120 can extend through only part of the thickness of the active layer 111, delimiting mesas of the layer 111 defining the pixels IPR of the sensor.

Whether the active layer 111 is fully or partially etched away into the trenches 120 can be selected depending on the desired compromise between photon-to-charge carrier conversion, dark current, and modulation transfer function. By reducing the volume available for photoelectric conversion, the complete etching of the active layer 111 in the trenches 120 tends to reduce quantum efficiency. By increasing the surface area of the sides and the quantity of defects created therein, full etching also tends to increase dark current. However, by isolating the pixels IPR from one another, full etching tends to limit optical and electrical cross-talk, thereby improving the modulation transfer function of the infrared sensor.

Preferably, the active infrared detection layer 111, the lower reflective layer 126, and the upper interface layer formed by the stack of layers 107 and 115, define a resonant cavity for the infrared radiation to be detected by the sensor.

To this end, the thickness of the active layer 111 and the thickness of the upper interface layer 107-115 are chosen so as to maximize the absorption of the infrared radiation of interest in the active layer 111, in a manner similar to that described in the aforementioned FR2113457 patent application.

In particular, the inventors have found that it is possible to obtain a very good resonant cavity even when the upper interface layer between the active infrared detection layer 111 and the active visible detection layer 101 made of silicon does not include a reflector. By reflector we mean a layer or stack of layers having, at the infrared wavelength in question, a reflection coefficient greater than 80%, for example greater than 50%, for example greater than 20%.

Thicknesses can be selected using standard photonic simulation tools. By way of example, the thickness of the active layer 111 is set to a desired value, preferably less than 1 μm, for example between 200 and 500 μm, then the thickness parameter of the upper oxide layer 107-115 is varied until an absorption peak is obtained.

Such a resonant cavity enables the active layer 111 to absorb more than 80%, for example 90% or more, of the infrared radiation of interest.

The thickness of the oxide layer 107-115 (sum of the thicknesses of layers 107 and 115) is for example between 10 nm and 800 nm, for example between 100 and 500 nm.

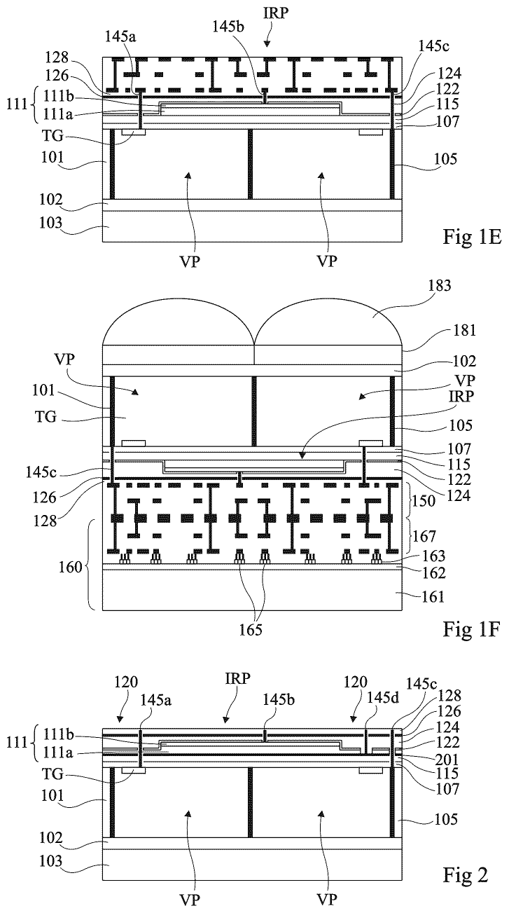

FIG. 2 is a cross-sectional view illustrating a variant of a visible and infrared image sensor according to one embodiment.

The variant shown in FIG. 2 comprises elements in common with the embodiment described in relation to FIGS. 1A-1F. These elements will not be detailed again below.

FIG. 2 illustrates the structure obtained at an intermediate stage in the method for manufacturing the sensor.

The steps leading to the structure shown in FIG. 2 are identical or similar to those described in relation to FIGS. 1A-1D, except that, in the example shown in FIG. 2, the structure comprises a doped semiconductor layer 201, for example of silicon, beneath and in contact with the active layer 111. By way of example, the layer 201 is formed on and in contact with the face of the active layer 111 opposite the initial substrate for supporting or growing the active layer 111, prior to forming the passivation layer 115. The assembly comprising the active layer 111, the doped semiconductor layer 201 and the passivation layer 115 is then transferred to the upper face of the structure shown in FIG. 1A, in a manner similar to that described above in relation to FIG. 1B.

The doped semiconductor layer 201 extends, for example, continuously and with a substantially uniform thickness over the entire surface of the sensor. The thickness of the doped semiconductor layer 201 is, for example, between 20 and 500 nm, e.g. of the order of 100 nm.

In the example shown in FIG. 2, the lateral insulation trenches 120 delimiting the islands or mesas of the active layer 111 extend over only part of the thickness of the active layer 111.

Alternatively, the trenches 120 can pass completely through the active layer 111 in a similar way to that described above in relation to FIGS. 1A-1F.

In the example shown in FIG. 2, however, the trenches 120 do not pass through the doped semiconductor layer 201. The 201 layer thus forms a doped baseplate electrically connecting the infrared photodetectors of the pixels IPR of the sensor via their lower face.

One or more insulated conductive vias 145d can be formed opposite the trenches 120 to make electrical contact with the layer 201. By way of example, a single via 145d common to all IRP pixels in the matrix may be provided, or several vias 145d, for example one per pixel or per group of pixels.

The following ùethod steps are, for example, identical or similar to those described above in relation to FIGS. 1E and 1F.

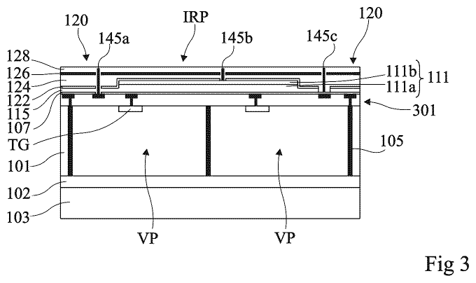

FIG. 3 is a cross-sectional view illustrating another variant of a visible and infrared image sensor according to one embodiment.

The variant shown in FIG. 3 comprises elements in common with the embodiment described in relation to FIGS. 1A to 1F. These elements will not be detailed again below.

FIG. 3 illustrates the structure obtained at an intermediate stage in the method for manufacturing the sensor.

The steps leading to the structure shown in FIG. 3 are identical or similar to those described in relation to FIGS. 1A-1D, except that, in the example shown in FIG. 3, the structure comprises an intermediate electrical routing structure 301 between the visible detection active layer 101 and the infrared detection active layer 111. The routing structure 301 comprises a stack of one or more insulating levels and one or more conducting levels in which electrical routing elements are formed. The electrical routing elements are preferably made of a semiconductor material that is transparent in the infrared pixel detection wavelength band, for example doped polycrystalline silicon.

By way of example, the routing structure is formed on the upper face of the visible detection active layer 101 after forming the visible pixels VP and before transferring the infrared detection active layer 111. Forming the routing structure 301 may involve successive steps of depositing and etching insulating and conductive layers on the upper surface of the visible detection active layer 101.

The routing elements of the structure 301 are connected, for example, to active elements of the visible pixels VP.

Providing the routing structure 301 advantageously allows the positioning of the active areas of the visible detection pixels VP to be relaxed. This allows, for example, the conductive vias 145a and 145c, allowing electrically contacting the active elements of the visible pixels VP, to be preferentially arranged in the etched zones 120 of the infrared detection semiconductor layer 111.

The following method steps are, for example, identical or similar to those described above in relation to FIGS. 1E and 1F.

Various embodiments and variants have been described. Those skilled in the art will understand that certain features of these embodiments can be combined and other variants will readily occur to those skilled in the art. In particular, the embodiments described are not limited to the examples of materials, dimensions, and wavelength ranges mentioned in the present description.

In addition, FIGS. 1A-1F describe an example embodiment in which the integrated control circuit 160 is manufactured separately, then transferred and attached by hybrid bonding to the active visible and infrared detection structure (step shown in FIG. 1F). Alternatively, an integrated circuit for controlling the visible and/or infrared pixels can be formed using sequential 3D technology in a similar way to that described in relation to FIGS. 1A-1K of the above-mentioned patent application FR2113457. In this case, a semiconductor layer, for example of silicon, can be transferred full plate onto the structure shown in FIG. 1C, and then electronic components, in particular transistors, can be formed in this layer. The conductive vias formed in the step shown in FIG. 1D then further pass through this semiconductor layer. An interconnect stack can then be formed on the semiconductor layer.

1. A visible and infrared image sensor, comprising:
a first active layer for detecting visible radiation, in which a plurality of visible detection pixels are defined; and
superimposed on the first active layer, a second active layer for detecting infrared radiation, in which a plurality of infrared detection pixels are defined,
the sensor further comprising, on the side of the face of the second active layer opposite the first active layer, a control integrated circuit superimposed on the first and second active layers,
wherein the sensor comprises isolation trenches extending vertically through at least part of the thickness of the second active layer, and laterally delimiting in the second active layer islands or mesas forming the infrared detection pixels.

2. The sensor according to claim 1, wherein said isolation trenches pass entirely through the second active layer.

3. The sensor according to claim 1, wherein said isolation trenches extend over only part of the thickness of the second active layer.

4. The sensor of claim 1, wherein the second active layer defines, in each infrared detection pixel, a vertical resonant optical cavity for said infrared radiation.

5. The sensor according to claim 1, wherein the first active layer and the second active layer are separated by a non-metallic interface layer, the interface layer being in contact, by a first face, with the first active layer and, by a second face, with the second active layer.

6. The sensor according to claim 5, wherein the interface layer is made of silicon oxide.

7. The sensor according to claim 5, wherein the interface layer comprises electrical routing elements made of doped polycrystalline silicon.

8. The sensor according to claim 1, wherein the first active layer is made of silicon.

9. The sensor according to claim 1, wherein the second active layer is made of an inorganic semiconductor material.

10. The sensor according to claim 1, wherein the second active layer contains germanium or silicon, for example a silicon-germanium alloy (SiGe), a silicon-germanium-carbon alloy (SiGeC).

11. The sensor according to claim 1, wherein the second active layer contains InGaAs or any other sensing semiconductor material from the III-V semiconductor family.

12. The sensor according to claim 1, comprising a reflective layer, for example made of metal or a doped semiconductor material, on the side of the face of the second active layer opposite the first active layer.

13. The sensor according to claim 1, further comprising a doped semiconductor layer arranged between the first active layer and the second active layer and electrically connecting, via their face facing the first active layer, the infrared detection pixels of the sensor.

14. The sensor according to claim 1, comprising conductive vias extending vertically through the isolation trenches, and electrically connecting active elements of the visible detection pixels to the control integrated circuit.

15. A method for manufacturing a visible and infrared image sensor, comprising the following successive steps:
a) providing a first active layer for detecting visible radiation, in which a plurality of visible detection pixels are defined;
b) attaching, by direct bonding, to the first active layer, a second active layer for detecting infrared radiation;
c) forming isolation trenches extending laterally through the second active layer, and laterally delimiting in the second active layer islands or mesas defining a plurality of infrared detection pixels in the second active layer; and
d) arranging, on the side of the face of the second active layer opposite the first active layer, a control integrated circuit superimposed on the first and second active layers.
